(19) United States
(12) Patent Application Publication
(10) Pub. No.: US 2022/0058982 A1
(43) Pub. Date: Feb. 24, 2022

(54) LOGIC TRUTH TABLE VALIDATION ASSEMBLY

(71) Applicant: MIMO learning, LLC, Littleton, CO (US)

(72) Inventors: Lisa Marie Smith, Littleton, CO (US); Brandon Scott Smith, Littleton, CO (US)

(21) Appl. No.: 17/404,968

(22) Filed: Aug. 17, 2021

Related U.S. Application Data
(60) Provisional application No. 62/706,458, filed on Aug. 18, 2020.

(51) Int. Cl. G09B 23/18; H03K 19/21; G09B 19/00

(52) U.S. Cl. CPC G09B 23/186; G09B 19/0053; H03K 19/21

(57) ABSTRACT

Assemblies, methods, apparatus, and systems for learning activities are described. An assembly may include a first section and a second section. The first section of the assembly may include a first surface area portion that has a first set of recesses with which to receive indication elements (e.g., marbles or balls). The second section of the assembly may include validation protrusions and an alignment mechanism for aligning the second section with the first surface area portion of the first section. A method of using the assembly may include positioning the indication elements in a subset of the first set of recesses and placing the second section over the first section. The method may also include determining whether the second section correctly seats with the first section of the assembly for validating correct positioning of the indication elements corresponding to a logic truth table.

### CROSS REFERENCES

The present Application for Patent claims the benefit of U.S. Provisional Patent Application No. 62/706,458 by Smith et al., entitled “LOGIC TRUTH TABLE VALIDATION ASSEMBLY,” filed Aug. 18, 2020, assigned to the assignee hereof, and expressly incorporated by reference herein.

### FIELD OF TECHNOLOGY

The present disclosure relates generally to learning activities, and more specifically to learning logic truth tables.

### BACKGROUND

Montessori education typically promotes a hands-on approach to learning. However, a need remains for hands-on teaching of abstract concepts involving mathematical and computer related concepts.

### SUMMARY

The described techniques relate to improved assemblies, methods, apparatus, and systems for learning logic truth tables. In some examples, a logic truth table validation assembly may include a first section with a surface area portion that has a set of recesses with which to receive indication elements (e.g., marbles or balls). The first section may include indicia related to a logic truth table (e.g., an AND logic truth table, OR logic truth table, XOR logic truth table, NOT logic truth table, NAND logic truth table, NOR logic truth table, XNOR logic truth table, etc.). Additionally or alternatively, a second section of the logic truth table validation assembly may include indicia related to the logic truth table. The second section of the logic truth table validation assembly may include a surface designed to face the surface area portion of the first section that has the first set of recesses. The surface of the second section of the logic truth table validation assembly may include validation protrusions for interacting with the set of recesses on the surface area portion of the first section of the logic truth table validation assembly. At least one of the first section or the second section may include an alignment mechanism for aligning the second section with the surface area portion of the first section of the logic truth table validation assembly.

A user of the logic truth table validation assembly may position the indication elements on a subset of the recesses located in surface area portion of the first section. The user may review indicia related to the logic truth table and place the second section of the logic truth table validation assembly over the first section. In doing so, the user may align the second section of the logic truth table validation assembly over the first section in accordance with an alignment mechanism for aligning the second section with the first section. Based on the positioning of indication elements in the subset of recesses and whether the second section properly seats with the first section, the logic truth table validation assembly indicates whether the user correctly interpreted the logic truth table learning exercise.

An assembly for learning logic truth tables is described. The assembly may include a first section including a first surface area portion. In some cases, the first surface area portion may have a first set of recesses. The assembly may also include a second section including a set of validation protrusions and an alignment mechanism for aligning the second section with the first surface area portion of the first section. Additionally, the assembly may include a set of indication elements. In some cases, each indication element of the set of indication elements may be receivable by each recess of the first set of recesses.

A method for learning logic truth tables is described. The method may include positioning a set of indication elements in a subset of a first set of recesses of a first surface area portion of a first section of an assembly. The method may also include placing a second section of the assembly over the first section of the assembly. In some cases, the second section may include a set of validation protrusions and an alignment mechanism for aligning the second section with the first surface area portion of the first section. Additionally, the method may include determining whether the second section of the assembly correctly seats with the first section of the assembly based on the positioned set of indication elements in the subset of the first set of recesses.

An assembly is described. The assembly may include a first section including a first surface area portion, the first surface area portion having a first set of multiple recesses, a second section including a set of multiple validation protrusions and an alignment mechanism for aligning the second section with the first surface area portion of the first section, and a set of multiple indication elements, each indication element of the set of multiple indication elements being receivable by each recess of the first set of multiple recesses.

Another assembly is described. The assembly may include a first section including a first surface area portion, the first surface area portion having a means for receiving a plurality of indication elements (e.g., a first set of multiple recesses), a second section including a means for validating and indication element (e.g., a set of multiple validation protrusions) and a means for aligning the second section with the first surface area portion of the first section (e.g., an alignment mechanism), and a means for occluding (e.g., a set of multiple indication elements).

An apparatus is described. The apparatus may include a processor, memory coupled with the processor, and instructions stored in the memory. The instructions may be executable by the processor to cause the apparatus to implement a method that includes a graphical representation of the assembly. For example, an assembly display object may include a first section including a first surface area portion, the first surface area portion having a first set of multiple recesses, a second section including a set of multiple validation protrusions and an alignment mechanism for aligning the second section with the first surface area portion of the first section, and a set of multiple indication elements, each indication element of the set of multiple indication elements be receivable by each recess of the first set of multiple recesses.

Another apparatus is described. The apparatus may include means for performing a method that includes a graphical representation of the assembly. For example, an assembly display object may include a first section including a first surface area portion, the first surface area portion having a first set of multiple recesses, a second section including a set of multiple validation protrusions and an alignment mechanism for aligning the second section with the first surface area portion of the first section, and a set of multiple indication elements, each indication element of the set of multiple indication elements being receivable by each recess of the first set of multiple recesses.

A non-transitory computer-readable medium storing code is described. The code may include instructions executable by a processor to perform a method that includes a graphical representation of the assembly. For example, an assembly display object may include a first section including a first surface area portion, the first surface area portion having a first set of multiple recesses, a second section including a set of multiple validation protrusions and an alignment mechanism for aligning the second section with the first surface area portion of the first section, and a set of multiple indication elements, each indication element of the set of multiple indication elements be receivable by each recess of the first set of multiple recesses.

In some examples of the assemblies, apparatuses, and non-transitory computer-readable medium described herein, the second section may be structured to be properly seated with the first section in accordance with the alignment mechanism and to at least partially enclose the set of multiple indication elements based on the set of multiple indication elements being positioned correctly in the first set of multiple recesses.

In some examples of the assemblies, apparatuses, and non-transitory computer-readable medium described herein, an indication element of the set of multiple indication elements may be structured to occlude a validation protrusion of the set of multiple validation protrusions based on the indication element being positioned incorrectly in a recess of the first set of multiple recesses such that the second section may be prohibited from being properly seated with the first section in accordance with the alignment mechanism.

In some examples of the assemblies, apparatuses, and non-transitory computer-readable medium described herein, the alignment mechanism for aligning the second section with the first surface area portion of the first section includes at least one of a flange member or a seating member.

In some examples of the assemblies, apparatuses, and non-transitory computer-readable medium described herein, the first section includes a second surface area portion, the second surface area portion having a second set of multiple recesses.

In some examples of the assemblies, apparatuses, and non-transitory computer-readable medium described herein, the second surface area portion may be non-overlapping with the first surface area portion on a surface of the first section.

In some examples of the assemblies, apparatuses, and non-transitory computer-readable medium described herein, a number of the second set of multiple recesses may be equal to a number of the set of multiple indication elements.

In some examples of the assemblies, apparatuses, and non-transitory computer-readable medium described herein, a number of the set of multiple indication elements may be equal to a number of non-occluded recesses of the first set of multiple recesses when the second section may be seated with the first section in accordance with the alignment mechanism.

In some examples of the assemblies, apparatuses, and non-transitory computer-readable medium described herein, a number of the set of multiple indication elements may be less than a number of the first set of multiple recesses.

In some examples of the assemblies, apparatuses, and non-transitory computer-readable medium described herein, at least one of the first section or the second section includes indicia of a logic truth table to be determined by positioning the set of multiple indication elements in the first set of multiple recesses.

In some examples of the assemblies, apparatuses, and non-transitory computer-readable medium described herein, the logic truth table to be determined include at least one of an AND logic truth table, OR logic truth table, XOR logic truth table, NOT logic truth table, NAND logic truth table, NOR logic truth table, or XNOR logic truth table.

A method is described. The method may include positioning a set of multiple indication elements in a subset of a first set of multiple recesses of a first surface area portion of a first section of an assembly, placing a second section of the assembly over the first section of the assembly, the second section including a set of multiple validation protrusions and an alignment mechanism for aligning the second section with the first surface area portion of the first section, and determining whether the second section of the assembly correctly seats with the first section of the assembly based on the positioned set of multiple indication elements in the subset of the first set of multiple recesses.

An apparatus is described. The apparatus may include a processor, memory coupled with the processor, and instructions stored in the memory. The instructions may be executable by the processor to cause the apparatus to position a set of multiple indication elements in a subset of a first set of multiple recesses of a first surface area portion of a first section of an assembly, place a second section of the assembly over the first section of the assembly, the second section including a set of multiple validation protrusions and an alignment mechanism for aligning the second section with the first surface area portion of the first section, and determine whether the second section of the assembly correctly seats with the first section of the assembly based on the positioned set of multiple indication elements in the subset of the first set of multiple recesses.

Another apparatus is described. The apparatus may include means for positioning a set of multiple indication elements in a subset of a first set of multiple recesses of a first surface area portion of a first section of an assembly, means for placing a second section of the assembly over the first section of the assembly, the second section including a set of multiple validation protrusions and an alignment mechanism for aligning the second section with the first surface area portion of the first section, and means for determining whether the second section of the assembly correctly seats with the first section of the assembly based on the positioned set of multiple indication elements in the subset of the first set of multiple recesses.

A non-transitory computer-readable medium storing code is described. The code may include instructions executable by a processor to position a set of multiple indication elements in a subset of a first set of multiple recesses of a first surface area portion of a first section of an assembly, place a second section of the assembly over the first section of the assembly, the second section including a set of multiple validation protrusions and an alignment mechanism for aligning the second section with the first surface area portion of the first section, and determine whether the second section of the assembly correctly seats with the first section of the assembly based on the positioned set of multiple indication elements in the subset of the first set of multiple recesses.

In some examples of the method, apparatuses, and non-transitory computer-readable medium described herein, the determining whether the second section of the assembly correctly seats with the first section of the assembly includes determining that the second section of the assembly incorrectly seats with the first section of the assembly and the method, apparatuses, and non-transitory computer-readable medium may include further operations, features, means, or instructions for repositioning at least one indication element of the set of multiple indication elements in the subset of the first set of multiple recesses of the first surface area portion of the first section of the assembly.

In some examples of the method, apparatuses, and non-transitory computer-readable medium described herein, the second section may be structured to be properly seated with the first section in accordance with the alignment mechanism and to at least partially enclose the set of multiple indication elements based on the set of multiple indication elements being positioned correctly in the first set of multiple recesses.

In some examples of the method, apparatuses, and non-transitory computer-readable medium described herein, an indication element of the set of multiple indication elements may be structured to occlude a validation protrusion of the set of multiple validation protrusions based on the indication element being positioned incorrectly in a recess of the first set of multiple recesses such that the second section may be prohibited from being properly seated with the first section in accordance with the alignment mechanism.

In some examples of the method, apparatuses, and non-transitory computer-readable medium described herein, the alignment mechanism for aligning the second section with the first surface area portion of the first section includes at least one of a flange member or a seating member.

In some examples of the method, apparatuses, and non-transitory computer-readable medium described herein, a number of the set of multiple indication elements may be equal to a number of non-occluded recesses of the first set of multiple recesses when the second section may be seated with the first section in accordance with the alignment mechanism.

In some examples of the method, apparatuses, and non-transitory computer-readable medium described herein, a number of the set of multiple indication elements may be less than a number of the first set of multiple recesses.

In some examples of the method, apparatuses, and non-transitory computer-readable medium described herein, at least one of the first section or the second section includes indicia of a logic truth table to be determined by positioning the set of multiple indication elements in the first set of multiple recesses.

In some examples of the method, apparatuses, and non-transitory computer-readable medium described herein, the logic truth table to be determined includes at least one of an AND logic truth table, OR logic truth table, XOR logic truth table, NOT logic truth table, NAND logic truth table, NOR logic truth table, or XNOR logic truth table.

### BRIEF DESCRIPTION OF THE DRAWINGS

FIG. 1 is a perspective view illustrating an example of a logic truth table validation assembly in accordance with aspects of the present disclosure.

FIG. 2 is a perspective view illustrating an example of using a logic truth table validation assembly in accordance with aspects of the present disclosure.

FIG. 3 is a plan view illustrating an example of an AND logic truth table validation assembly in accordance with aspects of the present disclosure.

FIG. 4 is a plan view illustrating an example of an OR logic truth table validation assembly in accordance with aspects of the present disclosure.

FIG. 5 is a plan view illustrating an example of an XOR logic truth table validation assembly in accordance with aspects of the present disclosure.

FIG. 6 is a plan view illustrating an example of a NOT logic truth table validation assembly in accordance with aspects of the present disclosure.

FIG. 7 shows a flowchart illustrating an example method for learning logic truth tables in accordance with aspects of the present disclosure.

FIG. 8 shows a diagram of a system including devices that supports techniques for learning logic truth tables in accordance with aspects of the present disclosure.

### DETAILED DESCRIPTION

Various aspects of the present disclosure relate to assemblies, methods, apparatus, and systems for learning logic truth tables. In some examples, a logic truth table validation assembly may provide isolation of computation and Boolean logic-based concepts, sensory exploration for a learner (e.g., a child, young student, or other user), control of error and allowance for correction of the error. For example, sensory exploration for the learning process may involve the use of materials (e.g., a first section of the assembly, a second section of the assembly, a set of indication elements) that may be arranged in a manner for providing sensory experiences for the learner that creates an appropriate metaphor or analogy the learned subject. Control of error can represent that the materials themselves (e.g., validation protrusions on the second section of the assembly) may preserve the integrity of a particular teaching or learning exercise, so that the learner can herself or himself identify mistakes in her or his own work.

The future growth of many industries relies upon the availability of a highly trained computer-savvy workforce. Growing such a workforce lies in developing STEM-based (Science, Technology, Engineering, and Mathematics) competencies an early age. Thus, introducing novel apparatus and techniques for teaching basic STEM curriculum to young learners is desirable. The logic truth table validation assemblies and methods described herein effectively teach learners the unique functions of Boolean logic operators AND, OR, XOR, NOT, NAND, NOR, XNOR, etc., thereby providing a foundation in computer processing. Aspects of the disclosure are illustrated by and described with reference to apparatus assemblies, a flowchart, and a system that relate to learning logic truth tables.

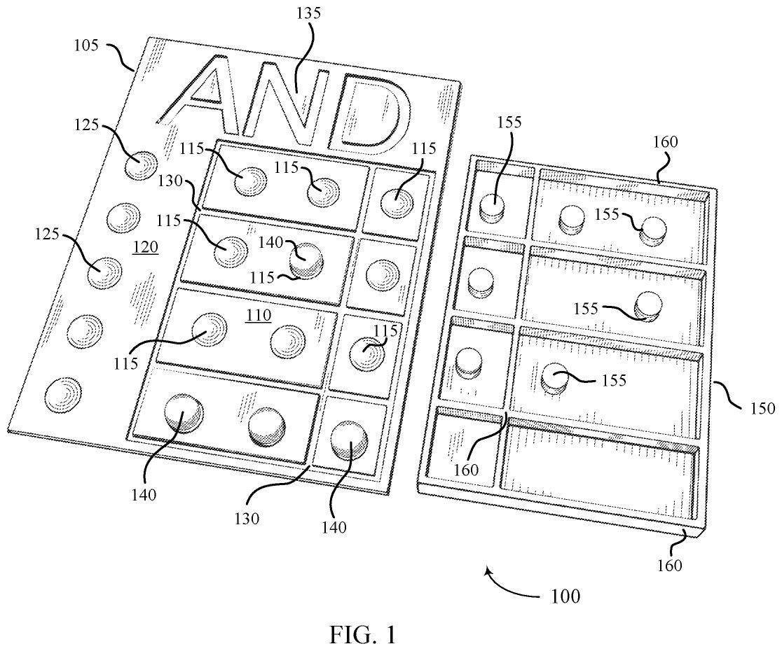

FIG. 1 is a perspective view illustrating an example of a logic truth table validation assembly in accordance with aspects of the present disclosure. Logic truth table validation assembly 100 may include a first section 105 (e.g., a base) and a second section 150 (e.g., a lid). First section 105 and second section 150 may be separate pieces or articles, but can be hinged, tethered, or otherwise coupled together in certain implementations.

First section 105 may include first surface area portion 110 that has recesses 115. In some examples, the recesses 115 may be, but are not limited to spherical indentations on the first surface area portion 110 for temporarily securing indication elements 140 in fixed positions. The indication elements 140 may be positioned on the recesses 115 of the first surface area portion 110. In some examples, the first section 105 may include a second surface area portion 120 that includes queue recesses 125 for the indication elements 140. That is, the indication elements 140 may be queued up in the queue recesses 125 and moved to various positions on the recesses 115 of the first surface area portion 110. In some examples, the second surface area portion 120 may be non-overlapping with the first surface area portion 110 on a surface of the first section 105.

In some examples, indicia 135 concerning the logic truth table associated with the logic truth table validation assembly 100 may be included on the first section 105. For example, indicia 135 concerning the logic truth table may include a statement “AND” indicating the type of logic truth table as shown in the example of FIG. 1. In other examples, indicia 135 concerning the logic truth table may include a specific color indicating the type of logic truth table (e.g., a color code scheme for indicating the type of logic truth table: red for an AND logic truth table, blue for an OR logic truth table, green for an XOR, logic truth table, etc.).

Second section 150 of the logic truth table validation assembly 100 may include validation protrusions 155 and an alignment mechanism for aligning the second section 150 with at least the first surface area portion 110 of the first section 105. For example, the second section 150 may include flange members 160 (e.g., walls or lips perpendicular to and protruding from a surface of the second section 150). Flange members 160 may be engageable with seating members 130 (e.g., channels or grooves on or within a surface of the first section 105). An alignment mechanism of the logic truth table validation assembly 100 can be included with one or both of the first section 105 and the second section 150. In this manner, the first section 105 and the second section 150 can be fixably and removably coupled together.

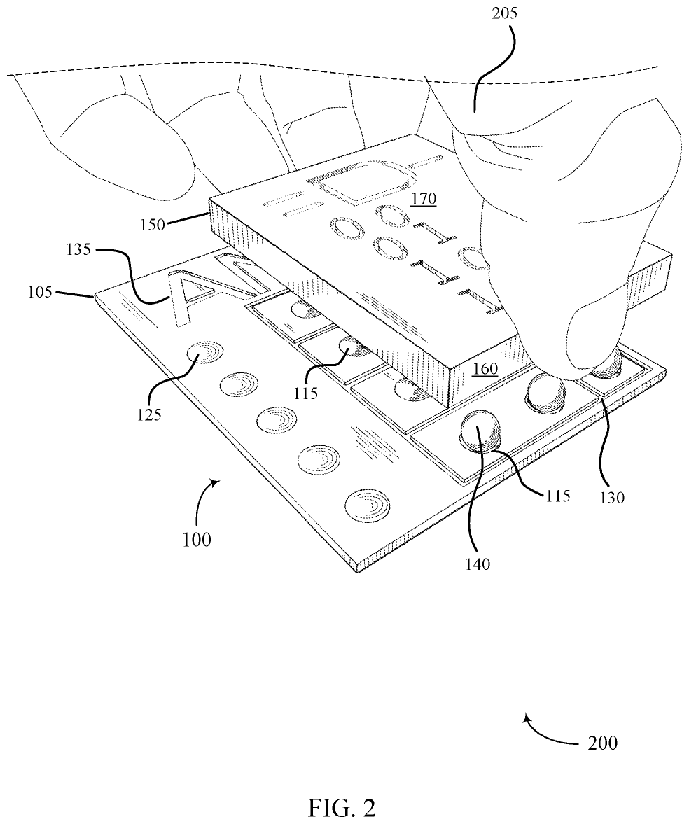

FIG. 2 is a perspective view illustrating an example of using a logic truth table validation assembly in accordance with aspects of the present disclosure. Learning exercise 200 may be performed by a learner 205 using logic truth table validation assembly 100.

Second section 150 of the logic truth table validation assembly 100 may include indicia 170 concerning the logic truth table associated with the logic truth table validation assembly 100. The indicia 170 concerning the logic truth table may include a circuit diagram of the corresponding logic truth table and a list of inputs. In some examples, the learner 205 is to calculate an output based on a corresponding input for the logic truth table. In other examples, the learner 205 is to calculate an input based on a corresponding output for the logic truth table.

At least one of the first section 105 or the second section 150 may include indicia concerning the logic truth table to be determined by positioning the indication elements 140 in the recesses 115 of the first surface area portion 110 of the first section 105. In some examples, indicia 170 concerning the logic truth table may be used by learner 205 in conjunction with the indicia 135 concerning the logic truth table included on the first section 105. In some examples, logic truth table indicia may be additionally provided in conjunction with one or both of indicia 135 of the first section 105 and indicia 170 of the second section 150 (e.g., provided in an accompanying instruction manual, video segment, or the like) In other examples, logic truth table indicia may be provided independent of the first section 105 and the second section 150 (e.g., provided in a standalone accompanying instructional materials).

In some examples, an indication element 140 in a recess 115 represents a “1” or a ‘high” value and an empty recess 115 (i.e., without an indication element 140 therein) represents a “0” or a ‘low” value. After each of the indication elements 140 are placed in corresponding input and output positions of the first surface area portion 110 of the first section 105, learner 205 place the second section 150 over the first section 105 in accordance with the alignment mechanism of the logic truth table validation assembly 100. If the second section 150 properly seats with the first section 105, then the indication elements 140 were correctly positioned by learner 205 for the corresponding input and output values of the logic truth table. That is, the second section 150 may be structured to be properly seated with the first section 105 in accordance with the alignment mechanism and to at least partially enclose the indication elements 140 based on the indication elements 140 being positioned correctly in the recesses 115.

If, however, the second section 150 does not properly seat with the first section 105 (e.g., due to one or more of the indication elements 140 occluding one or more of the validation protrusions 155 of the second section 150), then the indication elements 140 were incorrectly positioned by learner 205. A negatively-perceived sensory indication is provided to learner 205 by the second section 150 not properly seating with the first section 105 of logic truth table validation assembly 100. That is, an indication element 140 may be structured or sized in a manner to occlude a validation protrusion 155 based on the indication element 140 being positioned incorrectly in a recess 115 of either an input or output position of the first surface area portion 110 of the first section 105 such that the second section 150 may be prohibited from being properly seated with the first section 105.

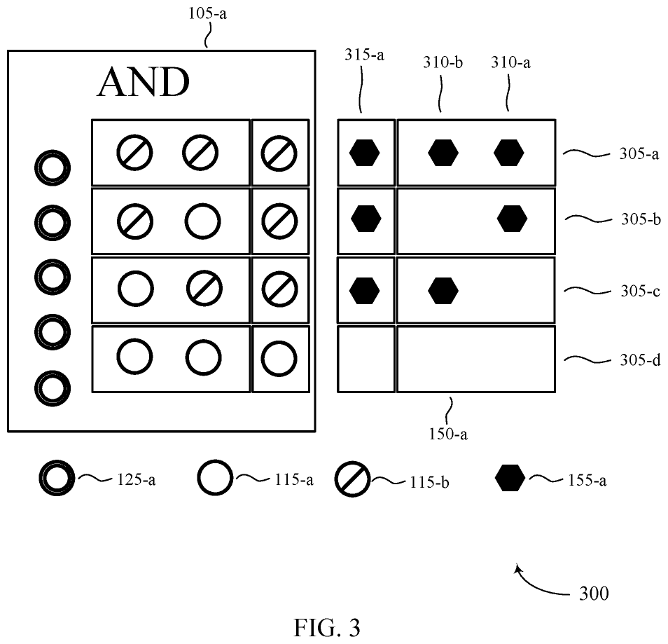

FIG. 3 is a plan view illustrating an example of an AND logic truth table validation assembly in accordance with aspects of the present disclosure. Logic truth table validation assembly 300 may include one or more aspects of the structures of or operations to be performed by logic truth table validation assembly 100 as described with reference to FIGS. 1 and 2.

Logic truth table validation assembly 300 may include first section 105-a and second section 150-a. In the example of FIG. 3, aspects of an AND logic truth table are described. The first section 105-a may include queue recesses 125-a, recesses 115-a intended to receive an indication element (e.g., an indication element representing a “1” or a ‘high” value), and recesses 115-b intended to be empty (e.g., an indication element representing a “0” or a ‘low” value). The second section 150-a may include validation protrusions 155-a arranged to validate rows 305-a, 305-b, 305-c, 305-d corresponding to input columns 310-a, 310-b and output column 315-a for the AND truth table. Respective rows, input columns, and output column represented by recesses 115-a, 115-b on an outer surface or face of the first section 105-a are mirrored with respect to a vertical or column orientation of an inner surface or inner face of the second section 150-a as shown in FIG. 3.

When a learner properly positions indication elements (e.g., marbles or balls) as identified by recesses 115-a, 115-b, the second section 150-a can be properly seated with the first section 105-a in accordance with an alignment mechanism of the logic truth table validation assembly 300 such that the outer surface or face of the first section 105-a and the inner surface or inner face of the second section 150-a are opposing surfaces or faces in a properly seated and validating arrangement. In some examples, a number of the queue recesses 125-a may be equal to a number of the indication elements provided for the logic truth table validation assembly 300. In some examples, a number of indication elements provided for the logic truth table validation assembly 300 may be equal to a number of recesses 115-b (i.e., non-occluded recesses) when the second section 150-a is properly seated with the first section 105-a in accordance with the alignment mechanism. In some examples, a number of the indication elements provided for the logic truth table validation assembly 300 may be less than a total number of recesses 115-a, 115-b.

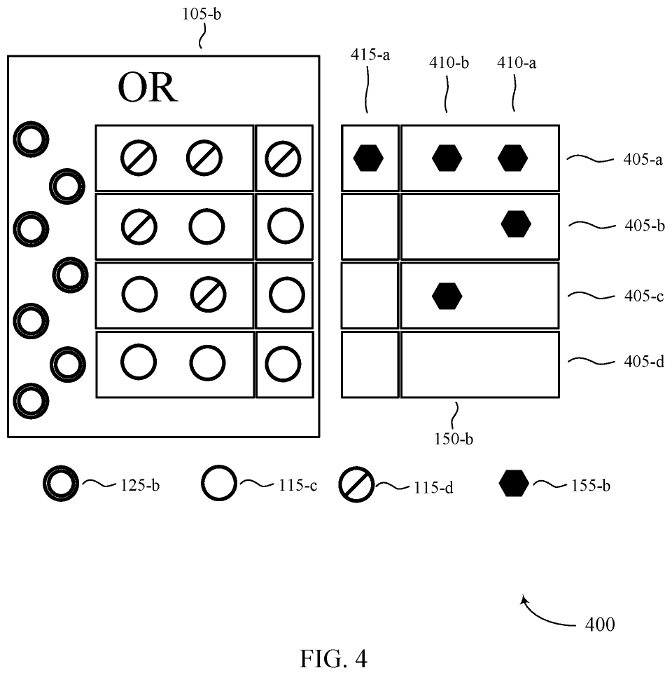

FIG. 4 is a plan view illustrating an example of an OR logic truth table validation assembly in accordance with aspects of the present disclosure. Logic truth table validation assembly 400 may include one or more aspects of the structures of or operations to be performed by logic truth table validation assembly 100 as described with reference to FIGS. 1 and 2.

Logic truth table validation assembly 400 may include first section 105-b and second section 150-b. In the example of FIG. 4, aspects of an OR logic truth table are described. The first section 105-b may include queue recesses 125-b, recesses 115-c intended to receive an indication element (e.g., an indication element representing a “1” or a ‘high” value), and recesses 115-d intended to be empty (e.g., an indication element representing a “0” or a ‘low” value). The second section 150-b may include validation protrusions 155-b arranged to validate rows 405-a, 405-b, 405-c, 405-d corresponding to input columns 410-a, 410-b and output column 415-a for the OR truth table. Respective rows, input columns, and output column represented by recesses 115-c, 115-d on an outer surface or face of the first section 105-b are mirrored with respect to a vertical or column orientation of an inner surface or inner face of the second section 150-b as shown in FIG. 4.

When a learner properly positions indication elements (e.g., marbles or balls) as identified by recesses 115-c, 115-d, the second section 150-b can be properly seated with the first section 105-b in accordance with an alignment mechanism of the logic truth table validation assembly 400 such that the outer surface or face of the first section 105-b and the inner surface or inner face of the second section 150-b are opposing surfaces or faces in a properly seated and validating arrangement. In some examples, a number of the queue recesses 125-b may be equal to a number of the indication elements provided for the logic truth table validation assembly 400. In some examples, a number of indication elements provided for the logic truth table validation assembly 400 may be equal to a number of recesses 115-d (i.e., non-occluded recesses) when the second section 150-b is properly seated with the first section 105-b in accordance with the alignment mechanism. In some examples, a number of the indication elements provided for the logic truth table validation assembly 400 may be less than a total number of recesses 115-c, 115-d.

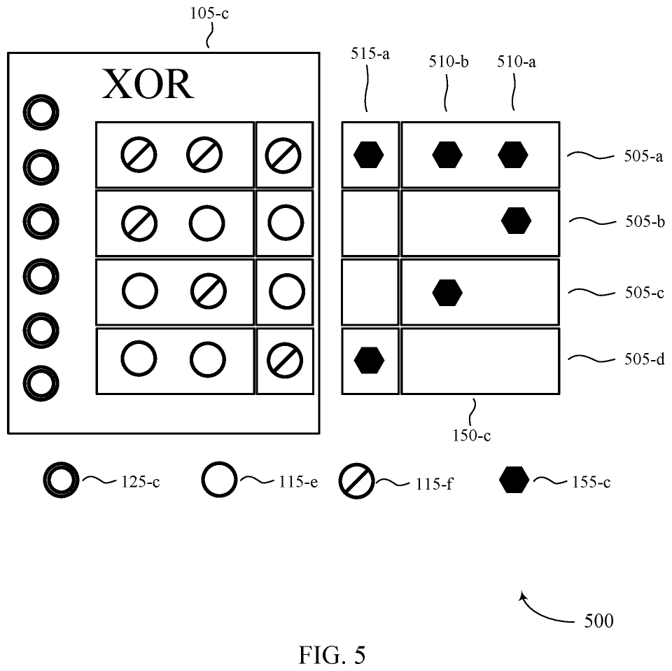

FIG. 5 is a plan view illustrating an example of an XOR logic truth table validation assembly in accordance with aspects of the present disclosure. Logic truth table validation assembly 500 may include one or more aspects of the structures of or operations to be performed by logic truth table validation assembly 100 as described with reference to FIGS. 1 and 2.

Logic truth table validation assembly 500 may include first section 105-c and second section 150-c. In the example of FIG. 5, aspects of an XOR logic truth table are described. The first section 105-c may include queue recesses 125-c, recesses 115-e intended to receive an indication element (e.g., an indication element representing a “1” or a ‘high” value), and recesses 115-f intended to be empty (e.g., an indication element representing a “0” or a ‘low” value). The second section 150-c may include validation protrusions 155-c arranged to validate rows 505-a, 505-b, 505-c, 505-d corresponding to input columns 510-a, 510-b and output column 515-a for the XOR truth table. Respective rows, input columns, and output column represented by recesses 115-e, 115-f on an outer surface or face of the first section 105-c are mirrored with respect to a vertical or column orientation of an inner surface or inner face of the second section 150-c as shown in FIG. 5.

When a learner properly positions indication elements (e.g., marbles or balls) as identified by recesses 115-e, 115-f, the second section 150-c can be properly seated with the first section 105-c in accordance with an alignment mechanism of the logic truth table validation assembly 500 such that the outer surface or face of the first section 105-c and the inner surface or inner face of the second section 150-c are opposing surfaces or faces in a properly seated and validating arrangement. In some examples, a number of the queue recesses 125-c may be equal to a number of the indication elements provided for the logic truth table validation assembly 500. In some examples, a number of indication elements provided for the logic truth table validation assembly 500 may be equal to a number of recesses 115-f (i.e., non-occluded recesses) when the second section 150-c is properly seated with the first section 105-c in accordance with the alignment mechanism. In some examples, a number of the indication elements provided for the logic truth table validation assembly 500 may be less than a total number of recesses 115-e, 115-f.

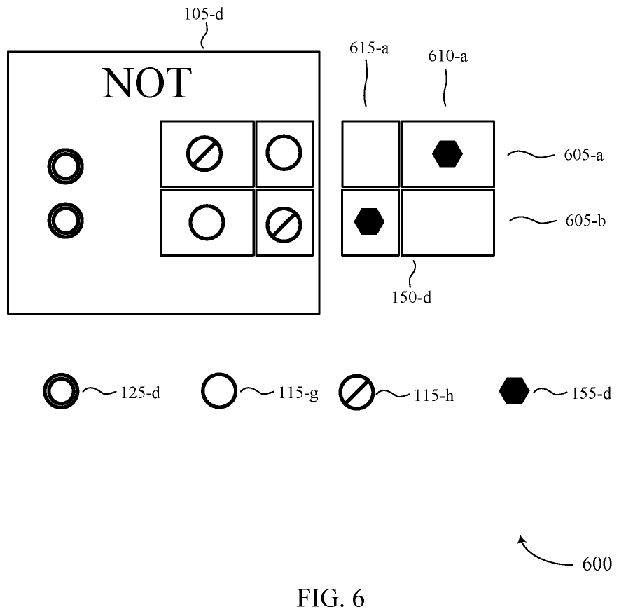

FIG. 6 is a plan view illustrating an example of a NOT logic truth table validation assembly in accordance with aspects of the present disclosure. Logic truth table validation assembly 600 may include one or more aspects of the structures of or operations to be performed by logic truth table validation assembly 100 as described with reference to FIGS. 1 and 2.

Logic truth table validation assembly 600 may include first section 105-d and second section 150-d. In the example of FIG. 6, aspects of a NOT logic truth table are described. The first section 105-d may include queue recesses 125-d, recesses 115-g intended to receive an indication element (e.g., an indication element representing a “1” or a ‘high” value), and recesses 115-h intended to be empty (e.g., an indication element representing a “0” or a ‘low” value). The second section 150-d may include validation protrusions 155-d arranged to validate rows 605-a, 605-b, corresponding to input column 610-a and output column 615-a for the NOT truth table. Respective rows, input column, and output column represented by recesses 115-g, 115-h on an outer surface or face of the first section 105-d are mirrored with respect to a vertical or column orientation of an inner surface or inner face of the second section 150-d as shown in FIG. 6.

When a learner properly positions indication elements (e.g., marbles or balls) as identified by recesses 115-g, 115-h, the second section 150-d can be properly seated with the first section 105-d in accordance with an alignment mechanism of the logic truth table validation assembly 600 such that the outer surface or face of the first section 105-d and the inner surface or inner face of the second section 150-d are opposing surfaces or faces in a properly seated and validating arrangement. In some examples, a number of the queue recesses 125-d may be equal to a number of the indication elements provided for the logic truth table validation assembly 600. In some examples, a number of indication elements provided for the logic truth table validation assembly 600 may be equal to a number of recesses 115-h (i.e., non-occluded recesses) when the second section 150-d is properly seated with the first section 105-d in accordance with the alignment mechanism. In some examples, a number of the indication elements provided for the logic truth table validation assembly 600 may be less than a total number of recesses 115-g, 115-h.

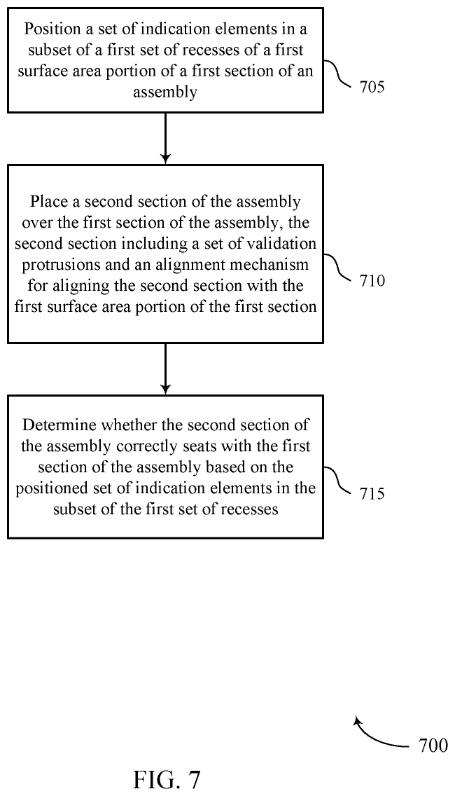

FIG. 7 shows a flowchart illustrating an example method 700 for learning logic truth tables in accordance with aspects of the present disclosure. The operations of method 700 may be implemented by a learner using a logic truth table validation assembly as described herein. In some examples, the method 700 may be implemented using an assembly that is a physical contraption (e.g., constructed from plastic, wood, metal, or like materials) of logic truth table validation assemblies described herein. In some examples, the method 700 may be implemented via devices using an assembly that is a graphical representation (e.g., a computing device generated construct or display object) of logic truth table validation assemblies described herein. It is to be understood that some aspects of the assembly may be omitted or modified for either a physical contraption or a graphical representation.

At 705, the learner may position a set of indication elements in a subset of a first set of recesses of a first surface area portion of a first section of an assembly. The operations of 705 may be performed according to the techniques described herein. In some examples, aspects of the operations of 705 may be performed with a logic truth table validation assembly as described with reference to FIGS. 1-6 and 8.

At 710, the learner may place a second section of the assembly over the first section of the assembly, the second section including a set of validation protrusions and an alignment mechanism for aligning the second section with the first surface area portion of the first section. The operations of 710 may be performed according to the techniques described herein. In some examples, aspects of the operations of 710 may be performed with a logic truth table validation assembly as described with reference to FIGS. 1-6 and 8.

At 715, the learner may determine whether the second section of the assembly correctly seats with the first section of the assembly based on the positioned set of indication elements in the subset of the first set of recesses. The operations of 715 may be performed according to the techniques described herein. In some examples, aspects of the operations of 715 may be performed with a logic truth table validation assembly as described with reference to FIGS. 1-6 and 8.

In some cases, the learner may determine that the second section of the assembly incorrectly seats with the first section of the assembly. In some cases, the learner may reposition at least one indication element of the plurality of indication elements in the subset of the first plurality of recesses of the first surface area portion of the first section of the assembly, for example, based on the determination that the second section of the assembly incorrectly seats with the first section.

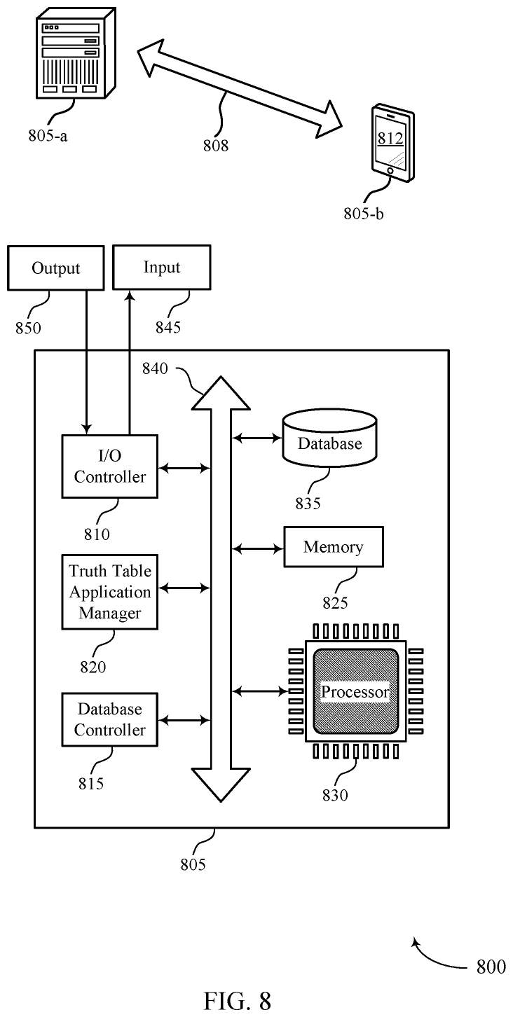

While examples have been illustrated and described, it will be appreciated that various changes can be made therein without departing from the spirit and scope of the present disclosure. It should also be appreciated by a person skilled in the art that one or more aspects of the present disclosure related to the logic truth table validation assemblies 100, 300, 400, 500, 600 discussed in the examples of FIGS. 1 through 6 along with the method 700 discussed in the example of FIG. 7 and system 800 discussed in the example of FIG. 8 may be implemented using an assembly modified so as to additionally or alternatively teach basic STEM curriculum other than the logic truth table learning exercises described herein.

FIG. 8 shows a diagram of a system 800 including devices 805 that supports techniques for learning logic truth tables in accordance with aspects of the present disclosure. In some cases, device 805 may be an example of a device 805-a (e.g., one or more logic truth table application servers) associated with the system 800 for learning logic truth tables. In some cases, device 805 may be an example of a user device 805-b (e.g., a user device such as but not limited to a desktop computer, a laptop, mobile phone, etc.) associated with the system 800 for learning logic truth tables. In some cases, device 805-a may communicate with user device 805-b (e.g., operated by a learner) in performing one or more techniques described herein.

In some cases, device 805-a may communicate with user device 805-b via an interaction 808 that may include communication via one or more communication links. Interaction 808 may include one-way or two-way communication. Data including information associated with logic truth tables may be included with the interaction 808. For example, user device 805-b may provide for display and interaction a logic truth table validation assembly as described with reference to FIGS. 1 through 7. That is, user device 805-b may have a display screen 812 (e.g., a monitor, touch screen, or the like) to effectuate user interaction. Some features of the logic truth table validation assemblies 100, 300, 400, 500, 600 discussed in the examples of FIGS. 1 through 6 may be omitted or modified for graphical representation of an assembly display object by user device 805-b in system 800.

The device 805 (e.g., device 805-a or user device 805-b) may include components for bi-directional data communications including components for transmitting and receiving communications, such as a truth table application manager 820, an I/O controller 810, a database controller 815, a memory 825, a processor 830, and a database 835. These components may be in electronic communication or otherwise coupled (e.g., operatively, communicatively, functionally, electronically, electrically) via one or more buses (e.g., a bus 840). Some components may be excluded from device 805-a and user device 805-b.

The I/O controller 810 may manage input signals 845 and output signals 850 for the device 805. The I/O controller 810 may also manage peripherals not integrated into the device 805. In some cases, the I/O controller 810 may represent a physical connection or port to an external peripheral. In some cases, the I/O controller 810 may utilize an operating system such as iOS®, ANDROID®, MS-DOS®, MS-WINDOWS®, OS/2®, UNIX®, LINUX®, watchOS®, wearOS®, Tizen®, or another known operating system. In other cases, the I/O controller 810 may represent or interact with a modem, a keyboard, a mouse, a touchscreen, a watch face, a remote control, or a similar device. In some cases, the I/O controller 810 may be implemented as part of a processor 830. In some examples, a user may interact with the device 805 via the I/O controller 810 or via hardware components controlled by the I/O controller 810.

The database controller 815 may manage data storage and processing in a database 835. In some cases, a user may interact with the database controller 815. In other cases, the database controller 815 may operate automatically without user interaction. The database 835 may be an example of a single database, a distributed database, multiple distributed databases, a data store, a data lake, or an emergency backup database. Memory 825 may include random-access memory (RAM) and ROM. The memory 825 may store computer-readable, computer-executable software including instructions that, when executed, cause the processor 830 to perform various functions described herein. In some cases, the memory 825 may contain, among other things, a, a basic I/O system (BIOS) which may control basic hardware or software operation such as the interaction with peripheral components or devices. Processor 830 may include an intelligent hardware device, (e.g., a general-purpose processor, a DSP, a CPU, a microcontroller, an ASIC, an FPGA, a programmable logic device, a discrete gate or transistor logic component, a discrete hardware component, or any combination thereof). In some cases, the processor 830 may be configured to operate a memory array using a memory controller. In other cases, a memory controller may be integrated into the processor 830. The processor 830 may be configured to execute computer-readable instructions stored in a memory 825 to perform various functions (e.g., functions or tasks supporting techniques for learning logic truth tables).

In accordance with some implementations, a learner may select and position, via user device 805-b, a set of indication element display objects on display screen 812 in a subset of a first set of recess display objects of a first section of the assembly display object. In some cases, the truth table application manager 820 may be configured as or otherwise support a means for these selecting, positioning, and displaying operations.

The learner may also select, via user device 805-b, a second section of the assembly display object to be placed over the first section of the assembly display object on display screen 812. The second section may include a set of validation protrusion display objects. In some cases, the truth table application manager 820 may be configured as or otherwise support a means for these selecting and displaying operations

The user device 805-b may determine whether the second section of the assembly display object correctly matches with the first section of the assembly display object based on the positioned set of indication element display objects in the subset of the first set of recess display objects. The user device 805-b may display the result of the determining operation. In some cases, the truth table application manager 820 may be configured as or otherwise support a means for these determining and displaying operations.

In some cases, for example when the user device 805-b determines that an indication element display object is positioned incorrectly in a recess display object of the first set of recess display objects, the learner may select and repositioning at least one indication element display object of the set of indication element display objects on display screen 812 in the subset of the first set of recess display objects of the first section of the assembly display object. In some cases, the truth table application manager 820 may be configured as or otherwise support a means for these selecting, repositioning, and displaying operations

In some implementations, the assembly display object may correspond to a logic truth table. Non-limiting examples of logic truth tables include an AND logic truth table, OR logic truth table, XOR logic truth table, NOT logic truth table, NAND logic truth table, NOR logic truth table, and XNOR logic truth table. In some examples, user device 805-b may receive or otherwise obtain data constructs of the logic truth tables from device 805 via interaction 808. In some cases, the truth table application manager 820 may be configured as or otherwise support a means for these receiving or obtaining operations by user device 805-b and/or the counterpart transmitting or providing operation by device 805-a.

Aspects of the present disclosure concern physical contraptions (e.g., with which young children may interact to form intuitions about concepts of computing), as well as computer-based examples for on-line learning or eLearning implementations disclosed herein.

In accordance with some implementations, a first computer-based example may comprise an apparatus. This apparatus is described with respect to aspects the present disclosure. The apparatus may include a processor, memory coupled with the processor, and instructions stored in the memory. The instructions may be executable by the processor to cause the apparatus to position a set of indication elements in a subset of a first set of recesses of a first surface area portion of a first section of an assembly, place a second section of the assembly over the first section of the assembly, the second section including a set of validation protrusions and an alignment mechanism for aligning the second section with the first surface area portion of the first section, and determine whether the second section of the assembly correctly seats with the first section of the assembly based on the positioned set of indication elements in the subset of the first set of recesses. In some examples, aspects of these operations may be performed with system 800 as described with reference to FIG. 8.

In accordance with some implementations, a second computer-based example may comprise another apparatus. This apparatus is described with respect to aspects the present disclosure. The apparatus may include means for positioning a set of indication elements in a subset of a first set of recesses of a first surface area portion of a first section of an assembly, placing a second section of the assembly over the first section of the assembly, the second section including a set of validation protrusions and an alignment mechanism for aligning the second section with the first surface area portion of the first section, and determining whether the second section of the assembly correctly seats with the first section of the assembly based on the positioned set of indication elements in the subset of the first set of recesses. In some examples, aspects of these operations may be performed with system 800 as described with reference to FIG. 8.

In accordance with some implementations, a third computer-based example may comprise a non-transitory computer-readable medium. For example, a non-transitory computer-readable medium storing code is described with respect to the present disclosure. The code may include instructions executable by a processor to position a set of indication elements in a subset of a first set of recesses of a first surface area portion of a first section of an assembly, place a second section of the assembly over the first section of the assembly, the second section including a set of validation protrusions and an alignment mechanism for aligning the second section with the first surface area portion of the first section, and determine whether the second section of the assembly correctly seats with the first section of the assembly based on the positioned set of indication elements in the subset of the first set of recesses. In some examples, aspects of these operations may be performed with system 800 as described with reference to FIG. 8.

With respect these computer-based examples, and as described in the example system 800 with reference to FIG. 8 and throughout the disclosure, various operations described in connection with the disclosure herein may be implemented or performed with a general-purpose processor, a digital signal processor (DSP), an application-specific integrated circuit (ASIC), a field-programmable gate array (FPGA) or other programmable logic device, discrete gate or transistor logic, discrete hardware components, or any combination thereof designed to perform the functions described herein. A general-purpose processor may be a microprocessor, but in the alternative, the processor may be any conventional processor, controller, microcontroller, or state machine. A processor may also be implemented as a combination of computing devices (e.g., a combination of a DSP and a microprocessor, multiple microprocessors, one or more microprocessors in conjunction with a DSP core, or any other such configuration).

The functions described herein may be implemented in hardware, software executed by a processor, firmware, or any combination thereof. If implemented in software executed by a processor, the functions may be stored on or transmitted over as one or more instructions or code on a computer-readable medium. Other examples and implementations are within the scope of the disclosure and appended claims.

Computer-readable media includes both non-transitory computer storage media and communication media including any medium that facilitates transfer of a computer program from one place to another. A non-transitory storage medium may be any available medium that can be accessed by a general purpose or special purpose computer. By way of example, and not limitation, non-transitory computer-readable media can comprise RAM, ROM, electrically erasable programmable read only memory (EEPROM), compact disk (CD) ROM or other optical disk storage, magnetic disk storage or other magnetic storage devices, or any other non-transitory medium that can be used to carry or store desired program code means in the form of instructions or data structures and that can be accessed by a general-purpose or special-purpose computer, or a general-purpose or special-purpose processor. Also, any connection is properly termed a computer-readable medium. For example, if the software is transmitted from a website, server, or other remote source using a coaxial cable, fiber optic cable, twisted pair, digital subscriber line (DSL), or wireless technologies such as infrared, radio, and microwave, then the coaxial cable, fiber optic cable, twisted pair, DSL, or wireless technologies such as infrared, radio, and microwave are included in the definition of medium. Disk and disc, as used herein, include CD, laser disc, optical disc, digital versatile disc (DVD), floppy disk and Blu-ray disc where disks usually reproduce data magnetically, while discs reproduce data optically with lasers. Combinations of the above are also included within the scope of computer-readable media.

It should be noted that the methods and techniques described herein describe possible implementations, and that the operations and the steps may be rearranged or otherwise modified and that other implementations are possible.

The following examples are given by way of illustration and provide an overview of aspects of the present disclosure. Aspects of the following examples may be combined with aspects or embodiments shown or discussed in relation to the figures or elsewhere herein.

Aspect 1: An assembly comprising: a first section comprising a first surface area portion, the first surface area portion having a first plurality of recesses; a second section comprising a plurality of validation protrusions and an alignment mechanism for aligning the second section with the first surface area portion of the first section; and a plurality of indication elements, each indication element of the plurality of indication elements being receivable by each recess of the first plurality of recesses.

Aspect 2: The assembly of aspect 1, wherein the second section is structured to be properly seated with the first section in accordance with the alignment mechanism and to at least partially enclose the plurality of indication elements based at least in part on the plurality of indication elements being positioned correctly in the first plurality of recesses.

Aspect 3: The assembly of any of aspects 1 through 2, wherein an indication element of the plurality of indication elements is structured to occlude a validation protrusion of the plurality of validation protrusions based at least in part on the indication element being positioned incorrectly in a recess of the first plurality of recesses such that the second section is prohibited from being properly seated with the first section in accordance with the alignment mechanism.

Aspect 4: The assembly of any of aspects 1 through 3, wherein the alignment mechanism for aligning the second section with the first surface area portion of the first section comprises at least one of a flange member or a seating member.

Aspect 5: The assembly of any of aspects 1 through 4, wherein the first section comprises a second surface area portion, the second surface area portion having a second plurality of recesses.

Aspect 6: The assembly of aspect 5, wherein the second surface area portion is non-overlapping with the first surface area portion on a surface of the first section.

Aspect 7: The assembly of any of aspects 5 through 6, wherein a number of the second plurality of recesses is equal to a number of the plurality of indication elements.

Aspect 8: The assembly of any of aspects 1 through 7, wherein a number of the plurality of indication elements is equal to a number of non-occluded recesses of the first plurality of recesses when the second section is seated with the first section in accordance with the alignment mechanism.

Aspect 9: The assembly of any of aspects 1 through 8, wherein a number of the plurality of indication elements is less than a number of the first plurality of recesses.

Aspect 10: The assembly of any of aspects 1 through 9, wherein at least one of the first section or the second section comprises indicia of a logic truth table to be determined by positioning the plurality of indication elements in the first plurality of recesses.

Aspect 11: The assembly of aspect 10, wherein the logic truth table to be determined comprise at least one of an AND logic truth table, OR logic truth table, XOR logic truth table, NOT logic truth table, NAND logic truth table, NOR logic truth table, or XNOR logic truth table.

Aspect 12: A method comprising: positioning a plurality of indication elements in a subset of a first plurality of recesses of a first surface area portion of a first section of an assembly; placing a second section of the assembly over the first section of the assembly, the second section comprising a plurality of validation protrusions and an alignment mechanism for aligning the second section with the first surface area portion of the first section; and determining whether the second section of the assembly correctly seats with the first section of the assembly based at least in part on the positioned plurality of indication elements in the subset of the first plurality of recesses.

Aspect 13: The method of aspect 12, wherein the determining whether the second section of the assembly correctly seats with the first section of the assembly comprises determining that the second section of the assembly incorrectly seats with the first section of the assembly, and the method further comprising: repositioning at least one indication element of the plurality of indication elements in the subset of the first plurality of recesses of the first surface area portion of the first section of the assembly.

Aspect 14: The method of any of aspects 12 through 13, wherein the second section is structured to be properly seated with the first section in accordance with the alignment mechanism and to at least partially enclose the plurality of indication elements based at least in part on the plurality of indication elements being positioned correctly in the first plurality of recesses.

Aspect 15: The method of any of aspects 12 through 14, wherein an indication element of the plurality of indication elements is structured to occlude a validation protrusion of the plurality of validation protrusions based at least in part on the indication element being positioned incorrectly in a recess of the first plurality of recesses such that the second section is prohibited from being properly seated with the first section in accordance with the alignment mechanism.

Aspect 16: The method of any of aspects 12 through 15, wherein the alignment mechanism for aligning the second section with the first surface area portion of the first section comprises at least one of a flange member or a seating member.

Aspect 17: The method of any of aspects 12 through 16, wherein a number of the plurality of indication elements is equal to a number of non-occluded recesses of the first plurality of recesses when the second section is seated with the first section in accordance with the alignment mechanism.

Aspect 18: The method of any of aspects 12 through 17, wherein a number of the plurality of indication elements is less than a number of the first plurality of recesses.

Aspect 19: The method of any of aspects 12 through 18, wherein at least one of the first section or the second section comprises indicia of a logic truth table to be determined by positioning the plurality of indication elements in the first plurality of recesses.

Aspect 20: The method of aspect 19, wherein the logic truth table to be determined comprise at least one of an AND logic truth table, OR logic truth table, XOR logic truth table, NOT logic truth table, NAND logic truth table, NOR logic truth table, or XNOR logic truth table.

Aspect 21: An assembly comprising one or more elements expressed as a “means for” performing a specified function included any of aspects 1 through 11. For example, an assembly may include a means for receiving an indication element similar in structure or equivalent to a plurality of recesses, a means for aligning a section or portion similar in structure or equivalent to an alignment mechanism, a means for occluding a validation protrusion similar in structure or equivalent to an indication element, a means for validating an indication element similar in structure or equivalent to a validation protrusion, etc.

Aspect 22: An apparatus comprising a processor; memory coupled with the processor; and instructions stored in the memory and executable by the processor to cause the apparatus to perform a method that includes a graphical representation of the assembly of any of aspects 1 through 11.

Aspect 23: An apparatus comprising at least one means for performing a method that includes a graphical representation of the assembly of any of aspects 1 through 11.

Aspect 24: A non-transitory computer-readable medium storing code the code comprising instructions executable by a processor to perform a method that includes a graphical representation of the assembly of any of aspects 1 through 11.

Aspect 25: An apparatus comprising a processor; memory coupled with the processor; and instructions stored in the memory and executable by the processor to cause the apparatus to perform a method that includes a graphical representation of the assembly of any of aspects 12 through 20.

Aspect 26: An apparatus comprising at least one means for performing a method that includes a graphical representation of the assembly of any of aspects 12 through 20.

Aspect 27: A non-transitory computer-readable medium storing code the code comprising instructions executable by a processor to perform a method that includes a graphical representation of the assembly of any of aspects 12 through 20.

The description set forth herein, in connection with the appended drawings, describes example configurations and does not represent all the examples that may be implemented or that are within the scope of the claims. The term “exemplary” used herein means “serving as an example, instance, or illustration,” and not “preferred” or “advantageous over other examples.” The detailed description includes specific details for the purpose of providing an understanding of the described techniques. These techniques, however, may be practiced without these specific details. In some instances, structures are modified or omitted in order to avoid obscuring the concepts of the described examples.

In the appended figures, similar components or features may have the same reference label. Further, various components of the same type may be distinguished by following the reference label by a dash and a second label that distinguishes among the similar components. If just the first reference label is used in the specification, the description is applicable to any one of the similar components having the same first reference label irrespective of the second reference label.

As used herein, including in the claims, “or” as used in a list of items (for example, a list of items prefaced by a phrase such as “at least one of” or “one or more of”) indicates an inclusive list such that, for example, a list of at least one of A, B, or C means A or B or C or AB or AC or BC or ABC (i.e., A and B and C). Also, as used herein, the phrase “based on” shall not be construed as a reference to a closed set of conditions. For example, an exemplary step that is described as “based on condition A” may be based on both a condition A and a condition B without departing from the scope of the present disclosure. In other words, as used herein, the phrase “based on” shall be construed in the same manner as the phrase “based at least in part on.”

The description herein is provided to enable a person skilled in the art to make or use the disclosure. Various modifications to the disclosure will be readily apparent to those skilled in the art, and the generic principles defined herein may be applied to other variations without departing from the scope of the disclosure. Thus, the disclosure is not limited to the examples and designs described herein, but is to be accorded the broadest scope consistent with the principles and novel features disclosed herein.

What is claimed is:

1. An assembly comprising:
a first section comprising a first surface area portion, the first surface area portion having a first plurality of recesses;
a second section comprising a plurality of validation protrusions and an alignment mechanism for aligning the second section with the first surface area portion of the first section; and
a plurality of indication elements, each indication element of the plurality of indication elements being receivable by each recess of the first plurality of recesses.

2. The assembly of claim 1, wherein the second section is structured to be properly seated with the first section in accordance with the alignment mechanism and to at least partially enclose the plurality of indication elements based at least in part on the plurality of indication elements being positioned correctly in the first plurality of recesses.

3. The assembly of claim 1, wherein an indication element of the plurality of indication elements is structured to occlude a validation protrusion of the plurality of validation protrusions based at least in part on the indication element being positioned incorrectly in a recess of the first plurality of recesses such that the second section is prohibited from being properly seated with the first section in accordance with the alignment mechanism.

4. The assembly of claim 1, wherein the alignment mechanism for aligning the second section with the first surface area portion of the first section comprises at least one of a flange member or a seating member.

5. The assembly of claim 1, wherein the first section comprises a second surface area portion, the second surface area portion having a second plurality of recesses.

6. The assembly of claim 5, wherein the second surface area portion is non-overlapping with the first surface area portion on a surface of the first section.

7. The assembly of claim 5, wherein a number of the second plurality of recesses is equal to a number of the plurality of indication elements.

8. The assembly of claim 1, wherein a number of the plurality of indication elements is equal to a number of non-occluded recesses of the first plurality of recesses when the second section is seated with the first section in accordance with the alignment mechanism.

9. The assembly of claim 1, wherein a number of the plurality of indication elements is less than a number of the first plurality of recesses.

10. The assembly of claim 1, wherein at least one of the first section or the second section comprises indicia of a logic truth table to be determined by positioning the plurality of indication elements in the first plurality of recesses.

11. The assembly of claim 10, wherein the logic truth table to be determined comprise at least one of an AND logic truth table, OR logic truth table, XOR logic truth table, NOT logic truth table, NAND logic truth table, NOR logic truth table, or XNOR logic truth table.

12. A method comprising:
positioning a plurality of indication elements in a subset of a first plurality of recesses of a first surface area portion of a first section of an assembly;
placing a second section of the assembly over the first section of the assembly, the second section comprising a plurality of validation protrusions and an alignment mechanism for aligning the second section with the first surface area portion of the first section; and
determining whether the second section of the assembly correctly seats with the first section of the assembly based at least in part on the positioned plurality of indication elements in the subset of the first plurality of recesses.

13. The method of claim 12, wherein the determining whether the second section of the assembly correctly seats with the first section of the assembly comprises determining that the second section of the assembly incorrectly seats with the first section of the assembly, and the method further comprising:
repositioning at least one indication element of the plurality of indication elements in the subset of the first plurality of recesses of the first surface area portion of the first section of the assembly.

14. The method of claim 12, wherein the second section is structured to be properly seated with the first section in accordance with the alignment mechanism and to at least partially enclose the plurality of indication elements based at least in part on the plurality of indication elements being positioned correctly in the first plurality of recesses.

15. The method of claim 12, wherein an indication element of the plurality of indication elements is structured to occlude a validation protrusion of the plurality of validation protrusions based at least in part on the indication element being positioned incorrectly in a recess of the first plurality of recesses such that the second section is prohibited from being properly seated with the first section in accordance with the alignment mechanism.

16. The method of claim 12, wherein the alignment mechanism for aligning the second section with the first surface area portion of the first section comprises at least one of a flange member or a seating member.

17. The method of claim 12, wherein a number of the plurality of indication elements is equal to a number of non-occluded recesses of the first plurality of recesses when the second section is seated with the first section in accordance with the alignment mechanism.

18. The method of claim 12, wherein a number of the plurality of indication elements is less than a number of the first plurality of recesses.

19. The method of claim 12, wherein at least one of the first section or the second section comprises indicia of a logic truth table to be determined by positioning the plurality of indication elements in the first plurality of recesses.

20. The method of claim 19, wherein the logic truth table to be determined comprise at least one of an AND logic truth table, OR logic truth table, XOR logic truth table, NOT logic truth table, NAND logic truth table, NOR logic truth table, or XNOR logic truth table.
